(19) United States
(12) Patent Application Publication
(10) Pub. No.: US 2021/0294519 A1
(43) Pub. Date: Sep. 23, 2021

(54) MEMORY SYSTEM AND CONTROL METHOD THEREOF

(71) Applicant: Kioxia Corporation, Tokyo (JP)

(72) Inventors: Sai CHANDRA TEJA RADHAPURAM, Kawasaki Kanagawa (JP); Marie TAKADA, Yokohama Kanagawa (JP)

(73) Assignee: Kioxia Corporation, Tokyo (JP)

(21) Appl. No.: 17/010,002

(22) Filed: Sep. 2, 2020

(30) Foreign Application Priority Data
Mar. 18, 2020 (JP) 2020-047792

(51) Int. Cl. G06F 3/06

(52) U.S. Cl. CPC G06F 3/0655; G06F 3/0604; G06F 3/0679

(57) ABSTRACT

A memory system includes a non-volatile memory and a controller. The non-volatile memory includes a plurality of non-volatile memory dies. The controller controls the non-volatile memory. The controller manages the history of a command issued to the non-volatile memory for each of the plurality of non-volatile memory dies, and when a read command directed to a first non-volatile memory die among the plurality of non-volatile memory dies is issued, predicts the temperature of the first non-volatile memory die based on the history of the command, and applies a voltage to the first non-volatile memory die to read the target data of the read command based on the predicted temperature.

### CROSS-REFERENCE TO RELATED APPLICATION(S)

This application is based upon and claims the benefit of priority from Japanese Patent Application No. 2020-047792, filed on Mar. 18, 2020, the entire contents of which are incorporated herein by reference.

### FIELD

Embodiments described herein relate generally to a memory system and a control method thereof.

### BACKGROUND

Memory systems such as an SSD (Solid State Drive) and a UFS (Universal Flash Storage) equipped with a NAND type flash memory (NAND memory) are known. Certain NAND memories may include a built-in temperature sensor. In a memory system, when data is read from a NAND memory or when a correction of data read from the NAND memory fails, a voltage (read voltage) to be applied to the NAND memory for reading the data from the NAND memory is corrected based on a temperature measured by a temperature sensor in the NAND memory.

However, the acquisition of temperature information from the NAND memory when accessing the NAND memory deteriorates the latency of the memory system.

### DESCRIPTION OF THE DRAWINGS

FIG. 1 is a diagram illustrating an example of an arrangement of a memory system according to a first embodiment.

FIG. 2 is a diagram illustrating an example of an arrangement of a NAND memory die in a NAND memory included in the memory system according to the first embodiment.

FIG. 3 is a diagram illustrating an example in which a value of a read voltage to be applied to the NAND memory die at the time of reading data shifts due to temperature change.

FIG. 4 is a diagram illustrating an example of a timing at which the memory system of the first embodiment predicts the temperature of the NAND memory die.

FIG. 5 is a diagram illustrating an example of temperature transition of the NAND memory die due to a data write operation.

FIG. 6 is a diagram illustrating an example of a command history management table used by the memory system of the first embodiment.

FIG. 7 is a diagram illustrating an example of monitor information generated by the memory system of the first embodiment.

FIG. 8 is a diagram illustrating a prediction of the temperature of the NAND memory die by a temperature prediction model in the memory system of the first embodiment.

FIG. 9 is a diagram illustrating a modification of the monitor information generated by the memory system of the first embodiment.

FIG. 10 is a diagram illustrating an example of a shift table used by the memory system of the first embodiment.

FIG. 11 is a flowchart illustrating a flow of a process of managing the command history management table, executed by the memory system of the first embodiment.

FIG. 12 is a flowchart illustrating a flow of a process of reading data from the NAND memory, executed by the memory system of the first embodiment.

FIG. 13 is a flowchart illustrating a flow of a process of optimizing the temperature prediction model, executed by the memory system of the first embodiment.

FIG. 14 is a flowchart illustrating a flow of a process of selecting a method of decoding data read from the NAND memory, executed by the memory system of the first embodiment.

FIG. 15 is a flowchart illustrating a flow of a process of writing data to a NAND memory, executed by a memory system according to a second embodiment.

FIG. 16 is a flowchart illustrating a flow of a process of preventing a command transmission to a NAND memory, executed by a memory system according to a third embodiment.

### DETAILED DESCRIPTION

Embodiments provide a memory system capable of improving latency, and a control method thereof.

In general, according to at least one embodiment, the memory system includes a non-volatile memory and a controller. The non-volatile memory includes a plurality of non-volatile memory dies. The controller controls the non-volatile memory. The controller is configured to:

manage the history of a command issued to the non-volatile memory for each of the plurality of non-volatile memory dies; when a read command directed to a first non-volatile memory die among the plurality of non-volatile memory dies is issued, predict the temperature of the first non-volatile memory die based on the history of the command; and apply a voltage to the first non-volatile memory die to read the target data of the read command based on the predicted temperature.

Hereinafter, embodiments will be described with reference to the drawings.

### First Embodiment

First, a first embodiment will be described.

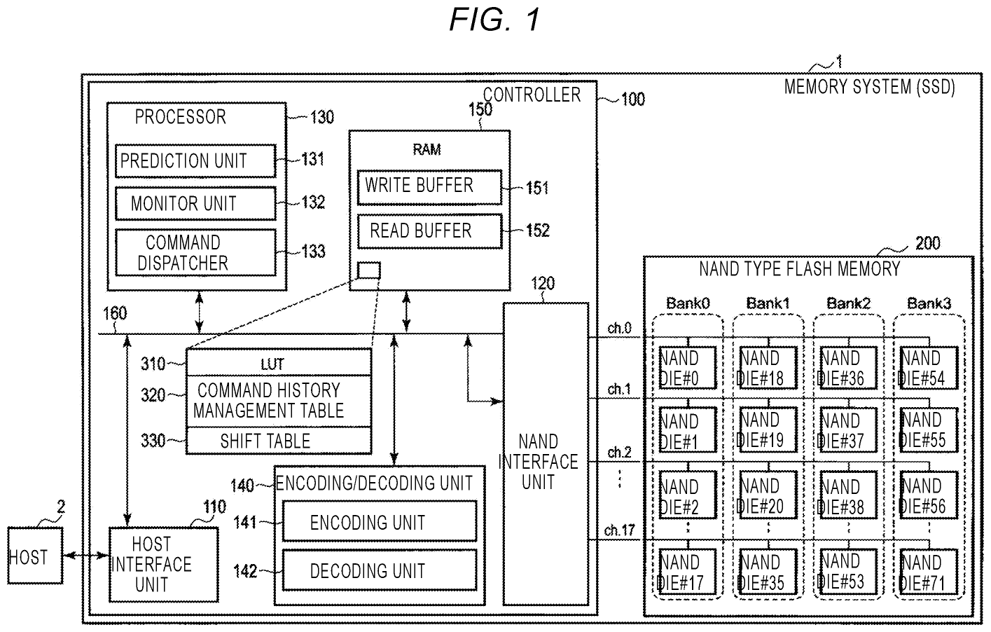

FIG. 1 is a diagram illustrating an example of the arrangement of a memory system 1 according to the first embodiment. Here, an example in which the memory system 1 is implemented as an SSD will be described.

The memory system 1, which is an SSD, includes a controller 100 configured as a semiconductor integrated circuit such as a SoC (System on a Chip), and a NAND type flash memory (NAND memory) 200.

The controller 100 includes a host interface unit 110, a NAND interface unit 120, a processor 130, an encoding and decoding unit 140, and a RAM 150. Each of these units is connected to an internal bus 160. The RAM 150 may be provided outside the controller 100. Further, the controller 100 stores an LUT (Look Up Table) 310, a command history management table 320, and a shift table 330 into, for example, the RAM 150. These tables are loaded from the NAND memory 200 onto the RAM 150 of the controller 100, for example, when the memory system 1 is started. Further, for example, when the memory system 1 is stopped, these tables are saved from the RAM 150 of the controller 100 to the NAND memory 200. The RAM 150 is, for example, SDRAM.

The host interface unit 110 is a device including a circuit that connects the memory system 1 and a host 2, and executes communication in accordance with, for example, the PCI Express (PCIe®) standard. The host interface unit 110 receives a command or data to be written to the NAND memory 200 (user data) from the host 2. The host interface unit 110 also transmits, to the host 2, user data read from the NAND memory 200.

The NAND interface unit 120 executes communication related to a write operation for writing data to the NAND memory 200 based on an instruction from the processor 130. Further, the NAND interface unit 120 executes communication related to a read operation for reading data from the NAND memory 200 based on an instruction from the processor 130. The NAND interface unit 120 includes a plurality of processing circuits for writing data to a plurality of NAND type flash memory dies (NAND dies #0 to #71) in the NAND memory 200 or reading data from the plurality of NAND dies #0 to #71. Although FIG. 1 illustrates 72 NAND dies #0 to #71, these are merely examples, and the number may be variously changed according to the specifications.

The NAND dies #XX (#0 to #71) include a memory cell array capable of storing data in a non-volatile manner and a peripheral circuit that controls the memory cell array. The NAND dies #XX may operate independently from each other. That is, a part of the NAND dies #0 to #71 functions as a parallel operation unit. The NAND dies #XX are also called a NAND type flash memory chip, a NAND memory chip, or a non-volatile memory chip.

The NAND dies #0 to #71 are connected to each of a plurality of channels Ch.0 to Ch.17 by the same number (e.g., four channels per channel). Each of the channels Ch.0 to Ch.17 includes a communication line (memory bus) for the NAND interface unit 120 to communicate with the NAND dies #0 to #71.

The eighteen NAND dies #0 to #17, the eighteen NAND dies #18 to #35, the eighteen NAND dies #36 to #53, and the eighteen NAND dies #54 to #71, which are connected one by one in parallel to each of the eighteen channels Ch.0-Ch.17, may be organized as banks (Bank 0 to Bank 3), respectively. The banks are units in which the plurality of NAND dies #XX operate in parallel by bank interleaving. In the configuration example illustrated in FIG. 1, the eighteen channels Ch.0 to Ch.17 allow the 72 NAND dies #0 to #71 to operate in parallel by bank interleaving using four banks.

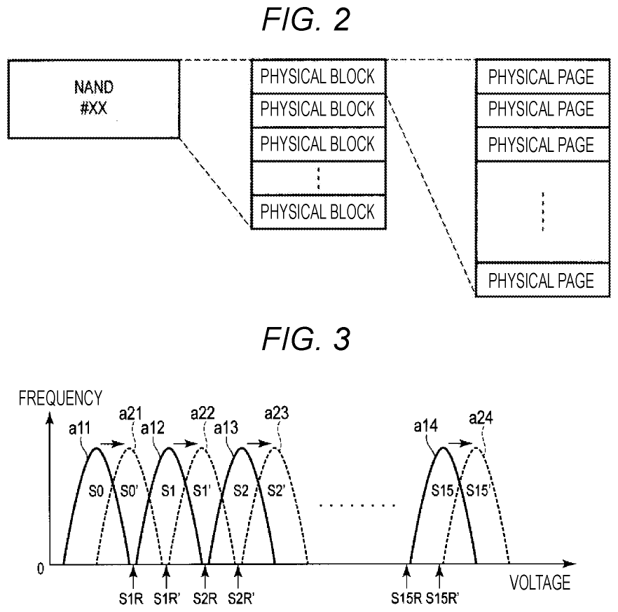

FIG. 2 is a diagram illustrating an example of the configuration of the NAND die #XX.

As illustrated in FIG. 2, the NAND die #XX includes a plurality of physical blocks each including a plurality of physical pages. Hereinafter, when simply called a block, the block indicates a physical block, and when simply called a page, the page indicates a physical page. Data writing and data reading are processed in page units. Meanwhile, data erasing is processed in block units. Data is not overwritten on the page where data is written. Therefore, updating data of the same logical address is performed by invalidating the original data written in a certain page and writing new data to another page.

The NAND die #XX stores data by injecting electrons into the floating gate of a memory cell. In addition, it is possible to store a plurality of bits of data into the memory cell of the NAND die #XX by controlling the amount of charges to be stored into the floating gate. Then, the data stored in the NAND die #XX may be read by applying a certain voltage, which is also called a read voltage, to the NAND die #XX.

A phenomenon called a temperature crossover exists in the NAND die #XX that stores data in this way. The temperature crossover may occur due to a change in the physical properties of the NAND die #XX according to temperature. The temperature crossover occurs due to a difference between a temperature of the NAND die #XX when writing data and a temperature of the NAND die #XX when reading data. That is, the temperature crossover is an event that a value of the read voltage for properly reading the data from the NAND die #XX shifts according to a difference from the temperature at the time of writing.

FIG. 3 is a diagram illustrating an example in which the value of the read voltage to be applied to the NAND die #XX at the time of reading data shifts due to a temperature change.

In the memory cell of the NAND die #XX, a current flows when a voltage equal to or higher than a voltage value corresponding to a charge amount of the floating gate is applied, and a current does not flow when a voltage lower than the voltage value is applied. The voltage at this boundary is called a threshold voltage. The memory system 1 associates data stored in the memory cells of the NAND die #XX with a plurality of distributions of threshold voltages (threshold voltage distributions). When writing data, the memory system 1 injects electrons into the floating gate of the memory cell so that a memory cell of a write destination corresponds to a threshold voltage distribution according to a data value.

For example, in a case where the memory cell in the NAND die #XX is a quad level cell (QLC) that stores 4-bit data “0000” to “1111”, there are 16 threshold voltage distributions (S0 to S15). The association between “0000” to “1111” and S0 to S15 may be set in various ways.

In FIG. 3, threshold voltage distributions indicated by symbols a11, a12, a13, and a14 (S0, S1, S14, and S15) are standard threshold voltage distributions assumed for the NAND die #XX. When reading data from the NAND die #XX, the memory system 1 may basically set voltage values that divide the standard threshold voltage distributions (S1R, S2R, . . . , S15R), as the read voltage.

In FIG. 3, threshold voltage distributions indicated by symbols a21, a22, a23 and a24 (S0′, S1′, S14′, and S15′) are threshold voltage distributions, for example, in a case where the temperature of the NAND die #XX exceeds a certain range to be risen. At this time, as illustrated in FIG. 3, the 16 threshold voltage distributions transitions from the above-described standard threshold voltage distribution state to a different state. Therefore, when reading data from the NAND die #XX in this situation, the memory system 1 needs to set voltage values that divide the threshold voltage distributions after the transition (S1R′, S2R′, . . . , S15R′), as the read voltage. A difference value between the voltage values S1R, S2R, . . . , S15R and the voltage values SIR′, S2R′, . . . , S15R′ is a shift offset value. The shift table 330 is a table that stores the association between the shift offset value and a temperature difference of the NAND die #XX between the time of writing data and the time of reading data.

As a measure against this phenomenon of temperature crossover, for example, at the time of reading data, a temperature measured by a temperature sensor provided in the NAND memory 200 is acquired from the NAND memory 200, and a shift offset value is calculated if necessary to appropriately correct the read voltage. However, in this case, an access to the NAND memory 200 for acquisition of the temperature information degrades a latency of the memory system 1.

Therefore, the memory system 1 according to at least one embodiment acquires a current temperature of the NAND die #XX (which has a smaller granularity than the NAND memory 200) without accessing the NAND memory 200 for acquisition of the temperature information, thereby improving the latency. Any known method may be used to record the temperature of the NAND die #XX at the time of writing data.

Referring back to FIG. 1, a description of the elements of the memory system 1 according to this embodiment will be continued.

The processor 130 executes a process corresponding to a command received from the host 2 connected via the host interface unit 110, and transmits the processing result to the host 2 via the host interface unit 110. The command received from the host 2 includes a write command requesting data write and a read command requesting data read. For example, the processor 130 executes writing of data to the NAND memory 200 and reading of data from the NAND memory 200 while using the RAM 150 as a temporary data storage area. Therefore, a write buffer 151, which is an area temporarily storing data to be written in the NAND memory 200, and a read buffer 152, which is an area temporarily storing data read from the NAND memory 200, are allocated in the RAM 150.

Further, when receiving the write command from the host 2, the processor 130 determines an area on the NAND memory 200 in which user data transferred from the host 2 is to be stored. That is, the processor 130 manages the correspondence relationship between a logical address designated by the write command and used by the host 2 to specify the data position and a physical address indicating an area on the NAND memory 200. The processor 130 uses the LUT 310, which is an address translation table, to manage the correspondence relationship between the logical address and the physical address. When receiving the read command from the host 2, the processor 130 translates a logical address designated by the read command into a physical address by referring to the LUT 310, and executes reading of data from the NAND memory 200. The translation from the logical address into the physical address is also called an address resolution.

The processor 130 may execute the writing of data to the NAND memory 200 and the reading of data from the NAND memory 200 under particular conditions in addition to the case of receiving the write command or the read command from the host 2. As described above, updating the data stored in the NAND memory 200 is performed by invalidating the original data on a certain page and writing new data to a different page. Therefore, a state in which a certain block is mostly occupied by unnecessary data (invalid data), may occur. For example, the processor 130 may execute writing of data to the NAND memory 200 and reading of data from the NAND memory 200 for a process called a garbage collection or a compaction for reusing an area where unnecessary data remains, which is targeted for such a block. In addition, for example, the processor 130 may execute writing of data to the NAND memory 200 and reading of data from the NAND memory 200 for a process called a refresh for re-storing valid data on the NAND memory 200 (moving or copying the valid data in the NAND memory 200).

Then, the processor 130 capable of reading data from the NAND memory 200 without being limited to the case of receiving the read command from the host 2 acquires the current temperature of the NAND die #XX (which has a smaller granularity than the NAND memory 200) without accessing the NAND memory 200 for acquisition of the temperature information. Further, the processor 130 calculates a shift offset value to correct the read voltage appropriately if necessary. The processor 130 includes a prediction unit 131, a monitor unit 132, and a command dispatcher 133, which will be described later, as elements related to reading data from the NAND memory 200.

The encoding and decoding unit 140 includes an encoding unit 141 and a decoding unit 142. The encoding unit 141 encodes data to be written in the NAND memory 200 to generate a codeword (data+ECC) including an error correction code (ECC). Although any encoding may be used as the encoding, for example, the RS (reed solomon) encoding, the BCH (Bose Chaudhuri Hocquenghem) encoding, and the LDPC (Low Density Parity Check) encoding may be used. The decoding unit 142 uses ECC to detect and correct an error of data read from the NAND memory 200 as a codeword together with the ECC. The decoding unit 142 may execute a hard-decision decoding that detects and corrects data error using the ECC, and a soft-decision decoding that decodes by an iterative calculation using a probability (calculation using the ECC), using a plurality of data read multiple times as different read voltages. The soft-decision decoding is typically used to recover severe data errors that the hard-decision decoding may not recover.

That is, the encoding and decoding unit 140 uses the user data received from the host 2 via the host interface unit 110 to generate a codeword including the user data, and stores the codeword into the write buffer 151 of the RAM 150. The encoding and decoding unit 140 also decodes data included in the codeword read from the NAND memory 200 via the NAND interface unit 120, and stores the data into the read buffer 152 of the RAM 150.

Next, the prediction unit 131, the monitor unit 132, and the command dispatcher 133 in the processor 130 will be described.

The prediction unit 131 predicts the temperature of the NAND die #XX according to the time-series issue status (e.g., schedule) of a command to the NAND die #XX. The command described herein is not a command received from the host 2 but a command issued by the processor 130 to the NAND interface unit 120. That is, this command includes a command voluntarily issued by the processor 130 for the above-described garbage collection and refresh. The types of the command include a write command for writing data to the NAND die #XX in page units, a read command for reading data from the NAND die #XX in page units, and an erase command for erasing data stored in the NAND die #XX in block units.

The monitor unit 132 monitors the issuance of a command by the processor 130 to the NAND memory 200, that is, the transmission of a command by the processor 130 to the NAND interface unit 120, and manages the history of the command. Specifically, the monitor unit 132 records a command issued by the processor 130 to the NAND memory 200 in the command history management table 320. The monitor unit 132 manages the history of the command so that it may be identified which of the NAND dies #XX is the target of the command. In other words, the monitor unit 132 manages the history of the command issued to the NAND memory 200 in a traceable manner for each of the NAND dies #XX. The history of the command managed by the monitor unit 132 includes the issue time and type of the command. The prediction unit 131 predicts the temperature of the NAND die #XX based on the history of the command managed by the monitor unit 132.

The command dispatcher 133 includes a command queue 1331 in which commands issued by the processor 130 to the NAND memory 200 are stored. The command dispatcher 133 sequentially takes out the commands from the command queue 1331 and transmits the commands to the NAND interface unit 120. The monitor unit 132 refers to the command queue 1331 to recognize the commands issued to the NAND memory 200. The monitor unit 132 may manage the history of the commands by recognizing the schedule of issuance of the commands to the NAND memory 200. When a read command is detected while referring to the command queue 1331, the monitor unit 132 notifies the prediction unit 131 that the read command exists in the command queue 1331. The prediction unit 131 predicts the temperature of the NAND die #XX that is the target of the read command.

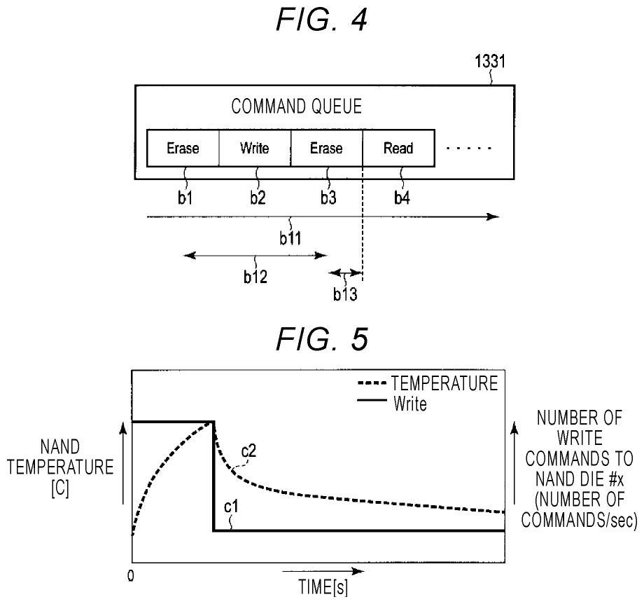

FIG. 4 is a diagram illustrating an example of a timing at which the temperature of the NAND die #XX is predicted by the memory system 1 according to the present embodiment having the configuration as above. The predicted temperature is used to adaptively adjust the read voltage to be applied to the NAND die #XX when reading data from the NAND die #XX.

For example, as illustrated in FIG. 4, an example will be described in which one or more commands are stored in the order of an erase command (Erase) b1, a write command (Write) b2, an erase command (Erase) b3, a read command b4 (Read), in the command queue 1331 of the command dispatcher 133. The one or more commands are commands to be issued by the processor 130 and transmitted to the NAND interface unit 120. That is, FIG. 4 illustrates an example in which the commands are processed in the order of an arrow indicated by symbol b11.

In this case, generally, after processing the 1st to 3rd commands sequentially, when the processing of the 4th read command b4 is started in order to cope with the temperature crossover or when the processing of the read command b4 fails, a measure is taken to acquire the temperature information from the NAND memory 200 and calculate a shift offset value to correct the read voltage.

In the memory system 1 according to at least one embodiment, first, the monitor unit 132 detects that the read command b4 exists in the command queue 1331. The existence of the read command b4 is notified from the monitor unit 132 to the prediction unit 131. The prediction unit 131 that received this notification predicts the temperature of the NAND die #XX that is the target of the read command b4. This prediction is performed in parallel with the processing of the other preceding command, for example, in a period denoted by symbol b12. The monitoring of commands in the command queue 1331 by the monitor unit 132 is also performed in parallel with the processing of commands. When the prediction unit 131 predicts the temperature, the processor 130 calculates a shift offset value based on the predicted temperature, if necessary, for example, in a period indicated by symbol b13.

In this way, in the memory system 1 according to at least one embodiment, the temperature of the NAND die #XX that is the target of the read command b4 is predicted at the timing when the existence of the read command b4 is detected before the processing of the read command b4 is started, and, if necessary, a shift offset value is calculated. Thus, the memory system 1 according to at least one embodiment reduces the possibility that the processing of the read command b4 fails due to the temperature crossover, and does not require an access to the NAND memory 200 for acquisition of the temperature. That is, the memory system 1 according to at least one embodiment may improve the latency.

Since the memory system 1 according to at least one embodiment may predict the temperature in units of NAND dies #XX having a smaller granularity as compared with the temperature in units of the NAND memory 200 or in units of a certain number of NAND dies #XX measured by one temperature sensor provided in the NAND memory 200, for example for all NAND dies #XX or for a certain number of NAND dies #XX, the read voltage may be corrected more appropriately. The unit in which the temperature is acquired may be smaller in granularity, such as a block unit that is an erase unit, or a page unit that is a read or write unit. That is, the read voltage may be corrected in the block unit or the page unit.

FIG. 5 is a diagram illustrating an example of temperature transition of the NAND die #XX due to a data write operation.

In FIG. 5, symbol c1 is a graph illustrating a transition of the number of write commands to the NAND die #XX in which the vertical axis represents the number of write commands to the NAND die #XX and the horizontal axis represents time. The number of write commands is represented by a number issued to the NAND die #XX in unit time (e.g., 1 second). Meanwhile, symbol c2 is a graph illustrating a temperature transition in which the vertical axis represents temperature and the horizontal axis represents time.

Here, as indicated by the graph c1, it is assumed a case where the number of write commands issued per second calms down after a situation where a large number of write commands is issued per second to a certain NAND die #XX continues for a certain period. Further, in this case, as indicated by the graph c2, it is assumed that the temperature of the NAND die #XX continues to rise while the situation where a large number of write commands is issued per second continues, and falls gradually when the number of write commands issued per second calms down.

Here, when the graph c2 may be represented by a function (model) that takes the execution status of the write command as an argument in consideration of the temperature characteristic of the NAND die #XX with respect to the write command, the temperature of the NAND die #XX may be predicted by inputting, as a model, information indicating the history of the command that the write command is executed as indicated in the graph c1, at any time in FIG. 5. With this model, the transition of the temperature of the NAND die #XX may be traced based on the execution status of the write command for the NAND die #XX, and the temperature of the NAND die #XX at any time may be predicted.

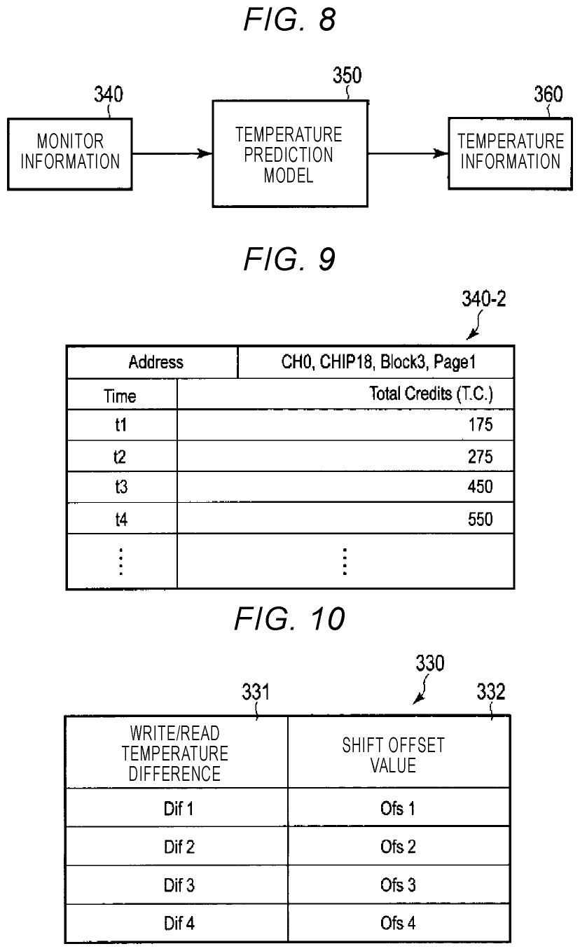

Although FIG. 5 illustrates an example of the transition of the temperature of the NAND die #XX due to the data write operation, it is possible to predict the temperature of the NAND die #XX by understanding the history of execution of the read command or the erase command without being limited to the write command. That is, the temperature of the NAND die #XX at any time may be predicted by preparing a model that combines the temperature characteristics of the NAND die #XX for each command. Therefore, the memory system 1 according to at least one embodiment prepares a model for predicting the temperature of the NAND die #XX from the command history including, for example, the command issue time and type (see a temperature prediction model 350 described in FIG. 8). The prediction unit 131 uses the temperature prediction model 350 to predict the temperature of the NAND die #XX when the read command is executed. The method of creating the temperature prediction model 350 is not limited to a specific method, and various known methods may be adopted.

FIG. 6 is a diagram illustrating an example of the command history management table 320.

The monitor unit 132 refers to the command queue 1331 of the command dispatcher 133 to record information on commands issued by the processor 130 to the NAND interface unit 120 in the command history management table 320.

In an Address field 321 of the command history management table 320, the NAND die #XX that is the target of the command is recorded in the unit of page. In a Time field 322, the command issuance time is recorded. This time may be, for example, the time at which the monitor unit 132 starts the periodical reference made by the command queue 1331 of the command dispatcher 133.

In a Program field 323, when the command for the page of the NAND die #XX recorded in the Address field 321 is a write command, a coefficient (score) set in advance for write is recorded. This coefficient is a value indicating the degree of temperature rise of the NAND die #XX. The coefficient is also referred to as credit. Here, it is assumed that 175 is set for write, 300 is set for erase, and 100 is set for read. A larger coefficient indicates a larger degree of temperature rise of the NAND die #XX. That is, the degree of temperature rise of the NAND die #XX has a relationship of read (100)<write (175)<erase (300). Similarly to the Program field 323, in the Erase field 324, when the command for the page of the NAND die #XX (the page included in the target block) recorded in the Address field 321 is the erase command, the coefficient (300) preset for the erase is recorded. Further, in the Read field, when the command for the page of the NAND die #XX recorded in the Address field 321 is the read command, the coefficient (100) preset for the read is recorded.

FIG. 6 illustrates a state where, as a result of the monitor unit 132 referring to the command queue 1331 of the command dispatcher 133, a write command for page 1 in block 3 of the NAND die #18 connected to the channel Ch.0 is detected, and 175, which is the coefficient preset for write for page 1 in block 3 of the NAND die #18, is recorded along with the time when the reference is started. Similarly, in the command history management table 320, information on the commands detected from the command queue 1331 of the command dispatcher 133 by the monitor unit 132 during the same period is recorded.

When the monitor unit 132 detects the read command by referring to the command queue 1331 of the command dispatcher 133, the monitor unit 132 notifies the prediction unit 131 that the read command exists in the command queue 1331 as described above. As described above, the read command detected at this time is not limited to the read command received from the host 2, but includes the one issued voluntarily by the processor 130 for the garbage collection or compaction.

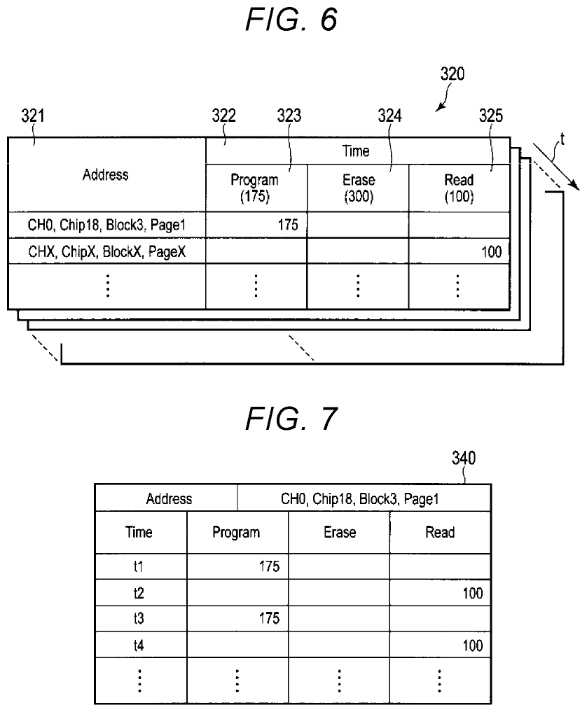

When the prediction unit 131 receives from the monitor unit 132 the notification that the read command exists in the command queue 1331 of the command dispatcher 133, the prediction unit 131 extracts from the command history management table 320 the information on the NAND die #XX that is the target of the read command, and generates monitor information 340. FIG. 7 illustrates an example of the monitor information 340.

FIG. 7 illustrates an example of the monitor information 340 generated when the target of the read command is page 1 in block 3 of the NAND die #18 connected to the channel Ch.0.

In the example of FIG. 7, for page 1 in block 3 of the NAND die #18 connected to the channel Ch.0, a write command is issued at time t1 and a read command is issued at time t2. Further, a write command is issued at time t3 and a read command is issued at time t4. That is, regarding page 1 in block 3 of the NAND die #18, the temperature rise factors of the coefficients 175, 100, 175, and 100 are generated at time t1 to t4, respectively. The values of time t1 to time t4 illustrated in FIG. 7 are values recorded in the Time field 322 of the command history management table 320 illustrated in FIG. 6, and the intervals of time t1 to time t4 are not necessarily equidistant.

As illustrated in FIG. 8, the prediction unit 131 inputs the generated monitor information 340 into the temperature prediction model 350 to acquire temperature information 360. That is, in the memory system 1 according to at least one embodiment, the temperature measured by the temperature sensor provided in the NAND memory 200, which is generally acquired by accessing the NAND memory 200, is predicted based on information on collected access history without accessing the NAND memory 200. Although not illustrated in FIG. 8, for example, the temperature predicted last time and its time are input to the temperature prediction model 350 together. These pieces of information are managed by, for example, the prediction unit 131. The prediction unit 131 stores, as initial values of these pieces of information, for example, the time when the memory system 1 is started, and a certain temperature, or a temperature acquired from the NAND memory 200 when the memory system 1 is started (a temperature measured by the temperature sensor provided in the NAND memory 200). In addition, the prediction unit 131 extracts information in the command history management table 320 in which the time after the point of time when the previous temperature is predicted is recorded, to generate the monitor information 340.

The monitor information 340 generated by the prediction unit 131 may be the total value of coefficients (Total Credits) at the present time without distinguishing the types of commands (monitor information 340_2), for example, as illustrated in FIG. 9. In this case, the temperature prediction model 350 may be simplified without considering the types of commands. In FIG. 9, although it is assumed that the write or read is continuously executed (when times t1 to t4 are continuous times), when the command is interrupted after a certain period of time elapses, the prediction unit 131 subtracts the total value of coefficients according to a period in which the command is interrupted. For example, when a period between time t3 and time t4 exceeds a certain period, the total value of coefficients at time t4 becomes a value smaller than 550 (450−n+100). The prediction unit 131 inputs the finally calculated total value of coefficients at the current point of time after the previous temperature is predicted, as the monitor information 340, to the temperature prediction model 350.

When the prediction unit 131 predicts the temperature, the processor 130 first determines whether the read voltage needs to be corrected. This determination is made, for example, by checking whether a difference value between temperatures at the time of writing data exceeds a threshold value. When it is determined that the read voltage needs to be corrected, the processor 130 refers to the shift table 330 to acquire a shift offset value.

FIG. 10 is a diagram illustrating an example of the shift table 330.

As illustrated in FIG. 10, the shift table 330 includes a write and read temperature difference field 331 and a shift offset value field 332.

In the write and read temperature difference field 331, a plurality of threshold values for acquiring the shift offset value from a temperature difference of the NAND die #XX between the time of writing data and the time of reading data is recorded, for example, in an ascending order. When the temperature difference of the NAND die #XX between the time of writing the data and the time of reading the data is equal to or larger than the value of the write and read temperature difference field 331 of the entry positioned at the head of the shift table 330, the processor 130 determines that the read voltage needs to be corrected. In the shift offset value field 332, shift offset values to be acquired for the threshold value of the write and read temperature difference field 331 are recorded in an ascending order.

In the case of the shift table 330 illustrated in FIG. 10, when the temperature difference of the NAND die #XX between the data writing time and the data reading time is Dif1 or more, the processor 130 determines that the read voltage needs to be corrected. When the temperature difference is Dif1 or more and less than Dif2, the processor 130 acquires Ofs1 as a shift offset value. Similarly, the processor 130 acquires Ofs2 as a shift offset value when the temperature difference is Dif2 or more and less than Dif3, and acquires Ofs3 as a shift offset value when the temperature difference is Dif3 or more and less than Dif4.

When the temperature difference is Dif4 or more, the processor 130 acquires Ofs4 as a shift offset value. When the temperature difference is an intermediate value of the values of the write and read temperature difference fields 331 of two entries of the shift table 330, the processor 130 may calculate a shift offset value to be acquired, from the values of the shift offset value fields 332 of the two entries.

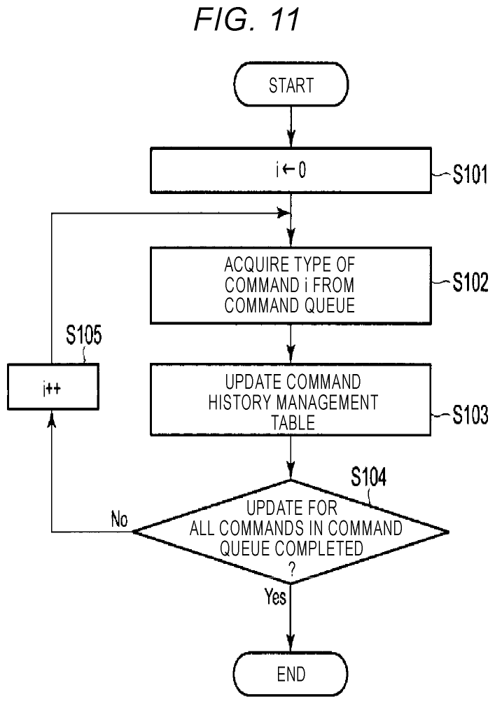

FIG. 11 is a flowchart illustrating the flow of a process of managing the command history management table 320, executed by the memory system 1.

The monitor unit 132 initializes a counter for sequentially referring to the command queue 1331 of the command dispatcher 133 (S101). The monitor unit 132 acquires the type of command of the entry indicated by the counter from the command queue 1331 of the command dispatcher 133 (S102). At this time, the monitor unit 132 also acquires information on the access target of the command, for example, in the unit of page.

The monitor unit 132 updates the command history management table 320 based on the information of the command including the type and the access target, which is acquired from the command queue 1331 of the command dispatcher 133 in S102 (S103). The monitor unit 132 determines whether the update of the command history management table 320 is completed for all the commands in the command queue 1331 of the command dispatcher 133 (S104). When there is an unprocessed command (“No” in S104), the monitor unit 132 increments the counter (S105) and repeats the process from S102. When the process of all the commands is completed (“Yes” in S104), the monitor unit 132 ends the process of managing the command history management table 320.

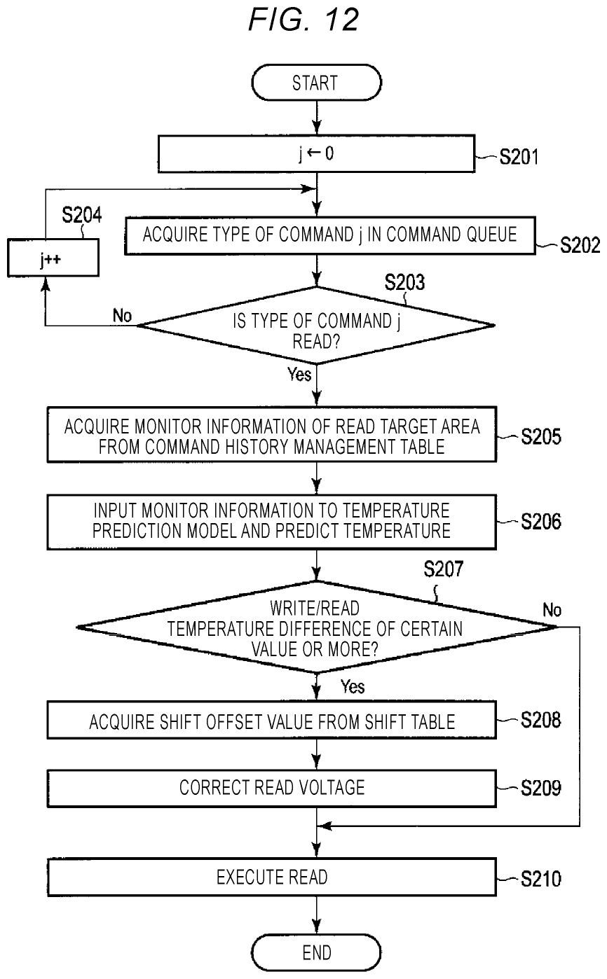

FIG. 12 is a flowchart illustrating the flow of a process of reading data from the NAND memory 200, executed by the memory system 1.

The monitor unit 132 initializes a counter for sequentially referring to the command queue 1331 of the command dispatcher 133 (S201). The monitor unit 132 acquires the type of command of the entry indicated by the counter in the command queue 1331 of the command dispatcher 133 (S202). When the command type is a read command (“Yes” in S203), the monitor unit 132 notifies the prediction unit 131 that the read command exists in the command queue 1331 of the command dispatcher 133. When the command type is not a read command (“No” in S203), the monitor unit 132 increments the counter (S204) and repeats the process from S202.

The prediction unit 131 that is received the notification from the monitor unit 132 acquires the monitor information 340 of the NAND die #XX that is the target of the read command, from the command history management table 320 managed by the monitor unit 132 (S205). The prediction unit 131 inputs the acquired monitor information 340 to the temperature prediction model 350 and predicts the temperature of the NAND die #XX (S206).

The processor 130 determines whether there is a difference of a certain value or more between the temperature predicted by the prediction unit 131 and the temperature of the NAND die #XX at the time of writing data to the NAND die #XX (S207). When it is determined that there is a difference of a certain value or more (“Yes” in S207), the processor 130 acquires a shift offset value corresponding to the difference from the shift table 330 (S208) and corrects the read voltage (S209). When it is determined that there is no difference of a certain value or more (“No” in S208), the processor 130 skips the processes of S208 and S209. Then, the processor 130 executes the reading of data from the NAND die #XX (S210).

S201 to S208 or S201 to S209 are processes that are executed in parallel with the process of other commands stored in the command queue 1331 of the command dispatcher 133 to be executed before the read command detected by the monitor unit 132.

In this way, the memory system 1 according to at least one embodiment may improve the latency by predicting the temperature of the NAND die #XX at the time of reading data without accessing the NAND memory 200 based on the history of commands.

As described above, the codeword including the ECC and the data is read from the NAND memory 200, decoded by the encoding and decoding unit 140 (the decoding unit 142), and stored into the read buffer 152. In addition, the decoding unit 142 may execute two types of decoding, that is, a hard-decision decoding and a soft-decision decoding. Usually, when the hard-decision decoding is executed and fails, the soft-decision decoding is executed.

In the memory system 1 according to at least one embodiment, since the temperature of the NAND die #XX for obtaining a shift offset value is predicted from the history of commands, an error in this prediction may cause, for example, a failure of the hard-decision decoding. Therefore, for example, when the hard-decision decoding fails, the memory system 1 according to at least one embodiment may again acquire the temperature measured by the temperature sensor provided in the NAND memory 200. In this case, the memory system 1 obtains the shift offset value to correct the read voltage based on the temperature obtained from the NAND memory 200, and re-executes the reading of data from the NAND memory 200. At this time, the memory system 1 feeds back the temperature acquired from the NAND memory 200 to the temperature prediction model 350. That is, the memory system 1 optimizes the temperature prediction model 350 based on the input data, the output data, and the data (correct answer) to be output. An optimization method is not limited to a specific method, but various known methods may be adopted.

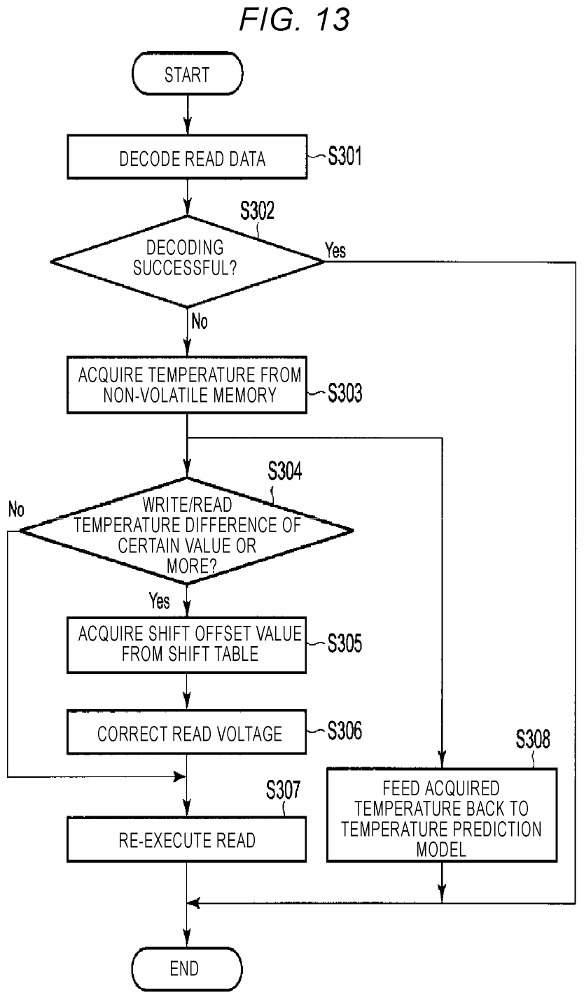

FIG. 13 is a flowchart illustrating the flow of a process of optimizing the temperature prediction model 350, executed by the memory system 1 when the reading of data fails. FIG. 13 illustrates the flow of a process subsequent to the process of S210 in FIG. 12.

The encoding and decoding unit 140 (the decoding unit 142) decodes the data read from the access target NAND die #XX of the NAND memory 200 (S301). When the decoding is successful (“Yes” in S302), the decoding unit 142 stores the decoded data into the read buffer 152. In this case, the process ends without re-reading the data from the NAND die #XX or optimizing the temperature prediction model 350.

When the decoding of the data by the decoding unit 142 fails (“No” in S302), the processor 130 acquires the temperature from the NAND die #XX (S303). The processor 130 determines whether there is a difference of a certain value or more between the acquired temperature and the temperature of the NAND die #XX at the time of writing data to the NAND die #XX (S304). When it is determined that there is a difference of a certain value or more (“Yes” in S304), the processor 130 acquires a shift offset value from the shift table 330 (S305) and corrects the read voltage (S306). When it is determined that there is no difference of a certain value or more (“No” in S304), the processor 130 skips the processes of S305 and S306. Then, the processor 130 re-executes the reading of data from the NAND die #XX (S307).

Further, the processor 130 feeds back the temperature, which is acquired from the NAND memory 200, to the temperature prediction model 350, for example, in parallel with the processes of S304 to S307, and optimizes the temperature prediction model 350 (S308).

Even in this case, since the frequency of acquiring the temperature from the NAND memory 200 is significantly reduced, the latency may be improved. Further, for example, it is possible to reflect the secular change or individual difference of the NAND memory 200 on the temperature prediction model 350.

In addition, the memory system 1 according to at least one embodiment predicts the temperature of the NAND die #XX that is the target of the read command before executing the read command, and acquires a shift offset value if necessary. A larger shift offset value may provide a higher possibility that the hard-decision decoding for detecting/correcting a data error using ECC will fail. Therefore, the memory system 1 according to at least one embodiment may execute the soft-decision decoding without going through the hard-decision decoding in anticipation of failure of the hard-decision decoding when a shift offset value is equal to or more than a threshold value.

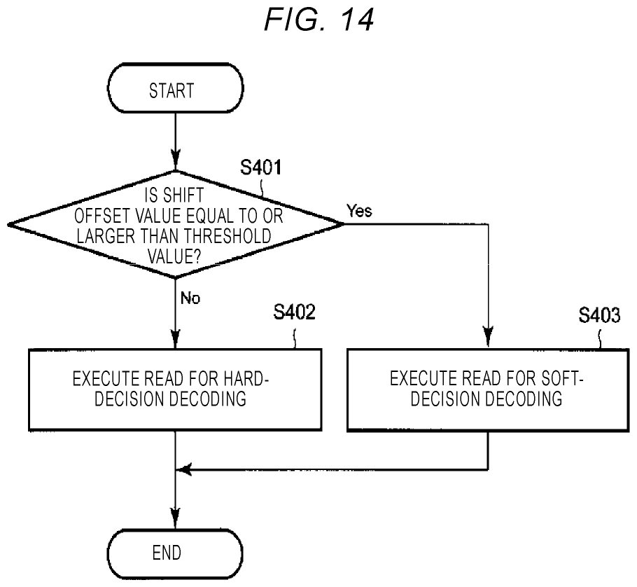

FIG. 14 is a flowchart illustrating the flow of a process of selecting a method of decoding data read from the NAND memory 200, executed by the memory system 1.

The processor 130 determines whether the shift offset value acquired from the shift table 330 is equal to or larger than a threshold value based on the temperature predicted by the prediction unit 131 (S401). When it is determined that the shift offset value is smaller than the threshold value (“No” in S401), the processor 130 executes the reading of data from the NAND memory 200 for the hard-decision decoding (S402). Specifically, normal data reading is executed. At this time, the processor 130 instructs the encoding and decoding unit 140 to perform the hard-decision decoding on the data read from the NAND memory 200.

In the meantime, when it is determined that the shift offset value is equal to or larger than the threshold value (“Yes” in S401), the processor 130 executes reading of data from the NAND memory 200 for the soft-decision decoding (S403). Specifically, the processor 130 executes data reading multiple times with different read voltages including the original read voltage corrected by a shift offset value, one or more read voltages lower than the original read voltage, and one or more voltages higher than the original read voltage. At this time, the processor 130 instructs the encoding and decoding unit 140 to perform the soft-decision decoding on the data read from the NAND memory 200.

In this case, the memory system 1 may improve the new latency by avoiding failure of the hard-decision decoding.

### Second Embodiment

Next, a second embodiment will be described.

Also in the second embodiment, as in the first embodiment, it is assumed that the memory system 1 is implemented as an SSD. The same elements as those of the memory system 1 of the first embodiment are denoted by the same reference numerals, and explanations thereof will not be repeated.

The first embodiment describes an example that, when a read command exists in the command queue 1331 of the command dispatcher 133, the temperature of the NAND die #XX that is the target of the read command is predicted, and if necessary, a shift offset value is acquired to correct the read voltage.

In the memory system 1 of the second embodiment, when a write command exists in the command queue 1331 of the command dispatcher 133, the temperature of the NAND die #XX that is the target of the write command is predicted. The write destination of data is determined by the processor 130 such that the number of times of use of the NAND dies #0 to #71 is equalized. Further, the prediction of the temperature of the NAND die #XX determined as the target of the write command by the processor 130 is executed by the prediction unit 131 using the command history management table 320 managed by the monitor unit 132, as in the first embodiment. The detection of the write command in the command queue 1331 of the command dispatcher 133 is also performed by the monitor unit 132 as in the first embodiment.

That is, in the second embodiment, upon detecting that a write command exists in the command queue 1331 of the command dispatcher 133, the monitor unit 132 notifies the prediction unit 131 that the write command exists. Upon receiving this notification, the prediction unit 131 acquires the monitor information 340 of the NAND die #XX, which is the target of the write command, from the command history management table 320 managed by the monitor unit 132. Then, the prediction unit 131 inputs the monitor information 340 to the temperature prediction model 350 and acquires the temperature information 360.

In the memory system 1 according to the present embodiment, when the temperature predicted by the prediction unit 131 is outside of a certain range, the processor 130 changes the write destination of data. Specifically, the NAND die #XX that is the target of the write command is changed. For example, writing data to the NAND die #XX at a temperature outside of the certain range, such as the temperature rising beyond an assumed range, is likely to cause an error. The memory system 1 according to at least one embodiment implements an improvement in latency by preventing an error that may occur due to writing data to the NAND die #XX at a temperature outside of a certain range. Further, since the writing of data to the NAND memory 200 is performed in the unit of page, the unit in which the temperature is acquired may be the unit having a smaller granularity, such as a block unit or a page unit, as in the first embodiment. That is, a determination as to whether the write destination of data needs to be changed and the selection of the change destination may be performed in the block unit or the page unit. For example, a block having a temperature within a certain range and a block having a temperature outside of the certain range may coexist in one NAND die #XX. Therefore, it is possible to change and write the write destination of data that is going to be written in a certain block of a certain NAND die #XX to another block of that NAND die #XX. The change of the writing destination may be implemented by changing a physical address associated with a logical address.

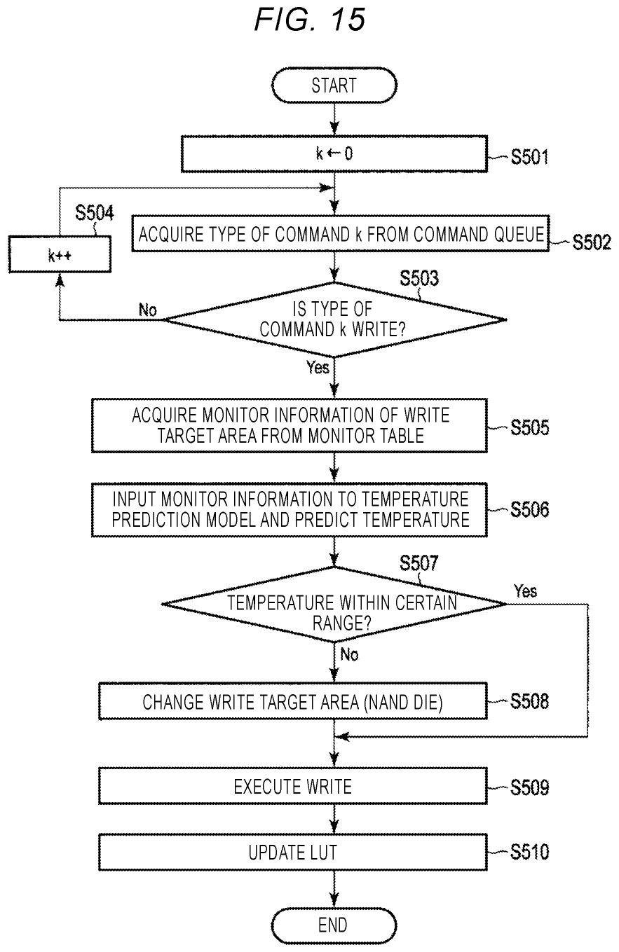

FIG. 15 is a flowchart illustrating the flow of a process of writing data to the NAND memory 200, executed by the memory system 1 of at least one embodiment.

The monitor unit 132 initializes a counter for sequentially referring to the command queue 1331 of the command dispatcher 133 (S501). The monitor unit 132 acquires the type of command of the entry indicated by the counter in the command queue 1331 of the command dispatcher 133 (S502). When the type of command is a write command (“Yes” in S503), the monitor unit 132 notifies the prediction unit 131 that the write command exists in the command queue 1331 of the command dispatcher 133. When the type of command is not a write command (“No” in S503), the monitor unit 132 increments the counter (S504) and repeats the process from S502.

Upon receiving the notification from the monitor unit 132, the prediction unit 131 acquires the monitor information 340 of the NAND die #XX that is the target of the write command (determined by the processor 130) from the command history management table 320 managed by the monitor unit 132 (S505). The prediction unit 131 inputs the acquired monitor information 340 to the temperature prediction model 350 and predicts the temperature of the NAND die #XX (S506).

The processor 130 determines whether the temperature predicted by the prediction unit 131 is within a certain range (S507). When it is determined that the temperature is outside of the certain range (“No” in S507), the processor 130 changes the NAND die #XX which is the target of the write command (S508). When it is determined that the temperature predicted by the prediction unit 131 is within the certain range (“Yes” in S507), the processor 130 skips the process of S508. Then, the processor 130 executes writing of data to the NAND die #XX (S509). After the writing of data, the processor 130 updates the LUT 310, which is an address translation table storing the association between a logical address and a physical address (S510).

In this way, the memory system 1 according to at least one embodiment may improve the latency by avoiding the writing of data to the NAND die #XX which is likely to cause an error.

An example is described above in which the NAND die #XX that is the target of the write command is changed when the predicted temperature of the NAND die #XX that is the target of the write command is outside of a certain range. Instead of such an example, when the predicted temperature is outside of a certain range, for example, a write speed (the number of operations or the write amount to the NAND die #XX per unit time) may be reduced. In this case as well, although the time required to write the data is extended, the occurrence of an error is prevented, and as a result, the latency may be improved.

### Third Embodiment

Next, a third embodiment will be described.

Also in the third embodiment, the memory system 1 implemented as an SSD is assumed as in the first and second embodiments. The same elements as those of the memory system 1 of the first and second embodiments are denoted by the same reference numerals, and explanations thereof will not be repeated.

In the first embodiment, the example is described in which when a read command exists in the command queue 1331 of the command dispatcher 133, the temperature of the NAND die #XX that is the target of the read command is predicted, and if necessary, a shift offset value is acquired to correct the read voltage.

Further, in the second embodiment, the example is described in which when a write command exists in the command queue 1331 of the command dispatcher 133, the temperature of the NAND die #XX, which is the target of the write command, is predicted, and when the predicted temperature is outside of a certain range, the NAND die #XX that is the target of the write command is changed.

In the memory system 1 according to the third embodiment, when a command existing in the command queue 1331 of the command dispatcher 133 is executed, the increased temperature of the NAND die #XX, which is the target of the command, is predicted in advance. Then, when the increased temperature is expected to exceed a threshold value, the memory system 1 according to at least one embodiment prevents the transmission of the command to the NAND interface unit 120 by the command dispatcher 133 for a required time. The required time may be a fixed value that is fixed in advance in common for all commands, may be a fixed value that is fixed in advance for each command type, or may be a value calculated adaptively based on the command type and the predicted temperature.

When the temperature exceeds the threshold value, an error may occur in the data stored in the NAND die #XX or a failure may occur in the NAND die #XX. The memory system 1 according to at least one embodiment has a non-operation period of the NAND die #XX for lowering the temperature of the NAND die #XX to prevent such a situation in advance. As a result, the memory system 1 according to the third embodiment eventually achieves an improvement in the latency.

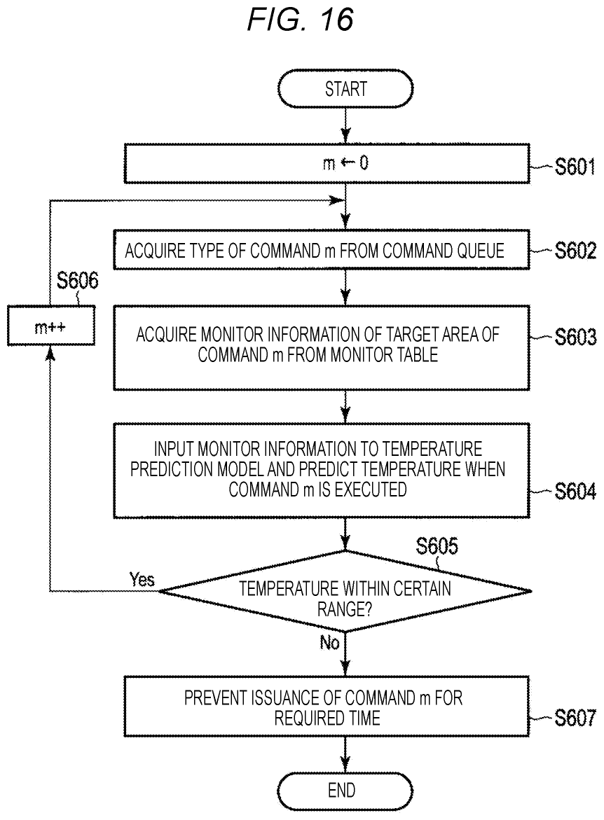

FIG. 16 is a flowchart illustrating the flow of a process of preventing a command transmission to the NAND memory 200, executed by the memory system 1 of the third embodiment.

The monitor unit 132 initializes a counter for sequentially referring to the command queue 1331 of the command dispatcher 133 (S601). The monitor unit 132 acquires the information of command of the entry indicated by the counter in the command queue 1331 of the command dispatcher 133 (S502). The monitor unit 132 transmits the information to the prediction unit 131.

The prediction unit 131 acquires the monitor information 340 of the NAND die #XX that is the target of the command, from the command history management table 320 managed by the monitor unit 132 based on the information received from the monitor unit 132 (S603). The prediction unit 131 inputs the acquired monitor information 340 to the temperature prediction model 350 and predicts the temperature of the NAND die #XX (S604).

The processor 130 determines whether the temperature predicted by the prediction unit 131 is within a certain range (S605). When it is determined that the temperature is within a certain range (“Yes” in S605), the processor 130 increments a counter (S606) and repeats the process from S602. When it is determined that the temperature predicted by the prediction unit 131 is outside of a certain range (“No” in S605), the processor 130 prevents the command dispatcher 133 from transmitting the command to the NAND interface unit 120 for a required time (S607).

In this way, the memory system 1 according to the third embodiment prevents the temperature of the NAND dies #0 to #71 from being outside of a certain range, which may cause an error of data stored in the NAND die #0 to #77 or a failure in the NAND die #0 to #77, thereby improving the latency.

In the above description, an example is described in which when the temperature of the NAND die #XX, which is the target of a command after execution of the command, is expected to be outside of a certain range, the transmission of the command from the command dispatcher 133 is prevented for a required time. Instead of such an example, when the temperature is expected to be outside of the certain range, the frequency of output of command from the command dispatcher 133 to the target NAND die #XX may be reduced. Also in this case, the temperature of the NAND die #XX is prevented from rapidly rising and exceeding a threshold value, and a situation that an error occurs in the data stored in the NAND die #XX or a failure occurs in the NAND die #XX is prevented, thereby improving the latency.

While certain embodiments have been described, these embodiments have been presented by way of example only, and are not intended to limit the scope of the disclosure.

Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the inventions.

(Supplementary Notes)

[1] The history of the command includes the issue time and type of the command, and the controller traces the transition of the temperature of the first non-volatile memory die based on the situation of issuance of the command to the first non-volatile memory die after the temperature is predicted, using the temperature of the first non-volatile memory chip die predicted before the issuance of the read command as a base temperature, and predicts the temperature of the first non-volatile memory die when the read command is issued.
[2] The controller includes a hard-decision decoding unit configured to perform a hard-decision decoding of data read from the non-volatile memory and a soft-decision decoding unit configured to perform a soft-decision decoding of the read data,

when the difference value is smaller than a first value, the hard-decision decoding unit performs the hard-decision decoding, and when the hard-decision decoding fails, the soft-decision decoding unit performs the soft-decision decoding, and

when the difference value is equal to or larger than the first value, the soft-decision decoding unit directly performs the soft-decision decoding without performing the hard-decision decoding by the hard-decision decoding unit.

[3] The non-volatile memory is a NAND type flash memory.
[4] The voltage to be applied is a voltage applied in the tracking read that determines the optimum value of the voltage for reading the data in response to an error in the data read from the first non-volatile memory chip.

What is claimed is:

1. A memory system comprising:
a non-volatile memory including a plurality of non-volatile memory dies; and
a controller configured to control the non-volatile memory,
wherein the controller is configured to:
manage a history of commands issued to the non-volatile memory for each of the plurality of non-volatile memory dies;
when a read command directed to a first non-volatile memory die among the plurality of non-volatile memory dies is issued, predict a temperature of the first non-volatile memory die based on the history of the commands; and
apply a voltage to the first non-volatile memory die to read target data of the read command based on the predicted temperature.

2. The memory system according to claim 1, wherein the controller is further configured to adjust a voltage to be applied to the first non-volatile memory die to read the target data based on a difference value between a temperature of the first non-volatile memory die when a write command for writing the target data has been issued and a temperature of the first non-volatile memory die predicted when the read command is issued.

3. The memory system according to claim 2, wherein the controller includes a temperature prediction model that combines temperature characteristics of the plurality of non-volatile memory dies for each command to predict temperatures of the plurality of non-volatile memory dies from the history of the commands.

4. The memory system according to claim 2, wherein the controller includes a hard-decision decoder configured to perform a hard-decision decoding of data read from the non-volatile memory and a soft-decision decoder configured to perform a soft-decision decoding of the read data,
wherein when the difference value is smaller than a first value, the hard-decision decoder is configured to perform the hard-decision decoding, and when the hard-decision decoding fails, the soft-decision decoder is configured to perform the soft-decision decoding, and
when the difference value is equal to or larger than the first value, the soft-decision decoder is configured to directly perform the soft-decision decoding without performing the hard-decision decoding by the hard-decision decoder.

5. The memory system according to claim 1, wherein the controller is further configured to:
when a write command directed to a second non-volatile memory die among the plurality of non-volatile memory dies is issued, predict a temperature of the second non-volatile memory die based on the history of the commands; and
when the predicted temperature is outside of a first range, change a write destination of target data of the write command from the second non-volatile memory die to a third non-volatile memory die, different from the second non-volatile memory die, among the plurality of non-volatile memory dies.

6. The memory system according to claim 1, wherein the controller is further configured to:
when a write command directed to a second non-volatile memory die among the plurality of non-volatile memory dies is issued, predict a temperature of the second non-volatile memory die based on the history of the commands; and
adjust a number of operations to the second non-volatile memory die per unit time based on the predicted temperature.

7. The memory system according to claim 6, wherein the controller is further configured to adjust the number of operations to the second non-volatile memory die per unit time lower as the predicted temperature of the second non-volatile memory increases.

8. The memory system according to claim 1, wherein the controller is further configured to:
manage an allowable temperature range of the plurality of non-volatile memory dies;
when a command directed to a second non-volatile memory die among the plurality of non-volatile memory dies is issued, predict a temperature of the second non-volatile memory die based on the history of the commands; and
when the predicted temperature is outside of the allowable temperature range, prevent the issuance of the command to the second non-volatile memory die, or lower a frequency of issuing the command to the second non-volatile memory die.

9. The memory system according to claim 1, wherein the controller includes a temperature prediction model based on temperature characteristics of the plurality of non-volatile memory dies for each command to predict temperatures of the plurality of non-volatile memory dies from the history of the commands.

10. The memory system according to claim 1, wherein the memory system is a solid state drive.

11. The memory system according to claim 1, wherein the history of the commands includes a command type and command issue time of the issued command.

12. A method of controlling a memory system having a non-volatile memory including a plurality of non-volatile memory dies, the method comprising:
managing a history of commands issued to the non-volatile memory for each of the plurality of non-volatile memory dies;
when a read command directed to a first non-volatile memory die among the plurality of non-volatile memory dies is issued, predicting a temperature of the first non-volatile memory die based on the history of the commands; and
applying a voltage to the first non-volatile memory die to read target data of the read command based on the predicted temperature.

13. The method according to claim 12, further comprising adjusting a voltage to be applied to the first non-volatile memory die to read the target data based on a difference value between a temperature of the first non-volatile memory die when a write command for writing the target data had been issued and a temperature of the first non-volatile memory die predicted when the read command is issued.

14. The method according to claim 12, further comprising:
when a write command directed to a second non-volatile memory die among the plurality of non-volatile memory dies is issued, predicting a temperature of the second non-volatile memory die based on the history of the commands; and
when the predicted temperature is outside of a first range, changing a write destination of target data of the write command from the second non-volatile memory die to a third non-volatile memory die, different from the second non-volatile memory die, among the plurality of non-volatile memory dies.

15. The method according to claim 12, further comprising:
when a write command directed to a second non-volatile memory die among the plurality of non-volatile memory dies is issued, predicting a temperature of the second non-volatile memory die based on the history of the commands; and
adjusting a number of operations to the second non-volatile memory die per unit time based on the predicted temperature.

16. The method according to claim 15, wherein the number of operations to the second non-volatile memory die per unit time are adjusted lower as the predicted temperature of the second non-volatile memory increases.

17. The method according to claim 12, further comprising:
managing an allowable temperature range of the plurality of non-volatile memory dies;
when a command directed to a second non-volatile memory die among the plurality of non-volatile memory dies is issued, predicting a temperature of the second non-volatile memory die based on the history of the commands; and
when the predicted temperature is outside of the allowable temperature range, preventing the issuance of the command to the second non-volatile memory die, or lowering a frequency of issuing the command to the second non-volatile memory die.

18. The method according to claim 12, further comprising combining temperature characteristics of the plurality of non-volatile memory dies for each command to predict temperatures of the plurality of non-volatile memory dies from the history of the commands.

19. The method according to claim 12, wherein the memory system is a solid state drive.

20. The method according to claim 12, wherein the history of the commands includes a command type and command issue time of the issued command.
